(19) United States
(12) Patent Application Publication
(10) Pub. No.: US 2024/0392439 A1
(43) Pub. Date: Nov. 28, 2024

(54) REACTOR LID AND AN ATOMIC LAYER DEPOSITION APPARATUS USING THE SAME

(71) Applicant: ASM IP Holding B.V., Almere (NL)

(72) Inventors: SungHoon Jun, Hwaseong-si (KR); DaeYoun Kim, Seo-gu (KR); Yonjong Jeon, Yongin-si (KR); Vivek Upadhaya, Hwaseong (KR)

(21) Appl. No.: 18/668,596

(22) Filed: May 20, 2024

Related U.S. Application Data
(60) Provisional application No. 63/468,466, filed on May 23, 2023.

(51) Int. Cl. C23C 16/455; C23C 16/44; C23C 16/458; C23C 16/46

(52) U.S. Cl. CPC C23C 16/45546; C23C 16/4412; C23C 16/45536; C23C 16/458; C23C 16/46

(57) ABSTRACT

A reaction lid and a Plasma Enhanced Atomic Layer Deposition (PEALD) apparatus with Remote Plasma Unit (RPU) using the reaction lid is disclosed. The reaction lid may comprise a gas inlet configured to flow a generated plasma and a processing gas into a wafer processing space, a top portion disposed below the gas inlet and having a truncated circular cone shape, the top portion defining the wafer processing space for flowing the generated plasma and the processing gas, a sidewall portion disposed below the top portion and a baffle placed at the mouth of the top portion below the gas inlet and configured to disperse the generated plasma and the processing gas throughout a surface of the wafer evenly by preventing the generated plasma and the processing gas from concentrating in the center of the wafer, wherein the wafer processing space is also defined by the sidewall portion.

### CROSS-REFERENCE TO RELATED APPLICATIONS

This application claims priority to U.S. Provisional Patent Application Ser. No. 63/468,466 filed May 23, 2023 titled A REACTOR LID AND AN ATOMIC LAYER DEPOSITION APPARATUS USING THE SAME, the disclosure of which is hereby incorporated by reference in its entirety.

### FIELD OF INVENTION

The present disclosure relates to a wafer processing apparatus, particularly to an ALD (Atomic Layer Deposition) apparatus equipped with a particular reactor lid.

### BACKGROUND OF THE DISCLOSURE

Wafer film uniformity, which has a direct impact on improving semiconductor yield, is becoming increasingly important in today's semiconductor deposition equipment.

For wafer quality, there are many conditions to be met, for example, plasma power, high temperature, various sources (gas), etc., therefore it is difficult to meet all the conditions with the existing equipment structure.

Plasma Enhanced Atomic Layer Deposition (PEALD) equipment for wafer deposition usually comprises upper electrode and lower electrode and a wafer is placed between the two electrodes for deposition processes. Usually, showerhead serves as an upper electrode and other structures like gas channel, inlet port, insulation parts and many other parts should also be present.

Due to the complexity of the conventional structure, it is often difficult to analyze the process results.

Therefore, the present disclosure presents a chamber structure which can replace the showerhead and an ALD apparatus using the chamber structure and a remote plasma unit for processing the wafers.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with one embodiment there may be provided, a reactor lid in an atomic layer deposition apparatus with a remote plasma unit to process wafers, the reactor lid comprising: a gas inlet configured to insert a generated plasma and a processing gas into a wafer processing space; a top portion disposed below the gas inlet and having a truncated circular cone shape, the top portion being configured for the generated plasma and the processing gas to be inserted into the wafer processing space; a sidewall portion disposed below the top portion; and a baffle placed at the mouth of the top portion below the gas inlet and configured to prevent the generated plasma and the processing gas from concentrating in the center of the wafer, wherein the wafer processing space being disposed below the top portion and surrounded by the sidewall portion.

In at least one aspect, the sidewall portion further comprising a plurality of holes around the bottom side of the sidewall portion.

In at least one aspect, the top portion further configured to have a downward convex shape.

In at least one aspect, the distance between neighboring two holes varies.

In at least one aspect, the diameter of the holes in the plurality of holes varies.

In accordance with another embodiment there may be provided, a Plasma Enhanced Atomic Layer Deposition (PEALD) apparatus for processing wafers, the apparatus comprising: a wafer support provided with a heater for supporting and heating a wafer; a remote plasma unit configured to generate plasma; a lower chamber configured to enclose the wafer support; an upper chamber configured to cover the lower chamber and provide a wafer processing space for processing wafers; and a gas inlet disposed to connect the remote plasma unit and the upper chamber, and the gas inlet being configured to insert the generated plasma from the remote plasma unit and a processing gas into the wafer processing space, wherein the upper chamber further comprises: a top portion disposed below the gas inlet and having a truncated circular cone shape, the top portion being configured for the generated plasma and the processing gas to be inserted into the wafer processing space; a sidewall portion disposed below the top portion; and a baffle placed at the mouth of the top portion below the gas inlet and configured to prevent the generated plasma and the processing gas from concentrating in the center of the wafer, wherein the wafer processing space being disposed below the top portion and surrounded by the sidewall portion and the wafer support.

In at least one aspect, the sidewall portion further comprising a plurality of holes around the bottom side of the sidewall portion.

In at least one aspect, the top portion further configured to have a downward convex shape.

In at least one aspect, a pumping port configured to exit the processing gas after processing wafers.

In at least one aspect, the distance between two neighboring holes of the plurality of holes would get shorter as the holes are located nearer to the pumping port.

In at least one aspect, the diameter of the holes of the plurality of holes would get larger as the holes are located nearer to the pumping port.

In accordance with another embodiment there may be provided, a reactor lid in an atomic layer deposition apparatus with a remote plasma unit to process wafers, the reactor lid comprising: a gas inlet configured to insert a generated plasma gas and a processing gas into a wafer processing space; a top portion disposed below the gas inlet and having a truncated circular cone shape, the top portion being configured for the generated plasma and dispersing a processing gas into a space below the top portion for processing the wafers; a sidewall portion disposed below the top portion; a baffle placed at the mouth of the top portion below the gas inlet and configured to prevent the generated plasma and the processing gas from concentrating in the center of the wafer; and more than one heater disposed on the surface of the top portion and/or around the gas inlet.

In at least one aspect, the sidewall portion further comprising a plurality of holes around the bottom side of the sidewall portion.

In at least one aspect, the top portion further configured to have a downward convex shape.

In at least one aspect, the distance between neighboring two holes and/or the diameter of the holes in the plurality of holes vary.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 illustrates one embodiment of a reactor lid according to the present disclosure.

FIG. 2 illustrates a from-the-bottom view of the reactor lid according to the present disclosure.

FIG. 3 illustrates how the distances between holes would vary in the reactor lid according to the present disclosure.

FIG. 4 illustrates the overall figure of the reactor lid and the plasma enhanced atomic layer deposition apparatus employing the reactor lid and a remote plasma unit according to an embodiment of the present disclosure.

FIG. 5 illustrates another embodiment of a reactor lid according to the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

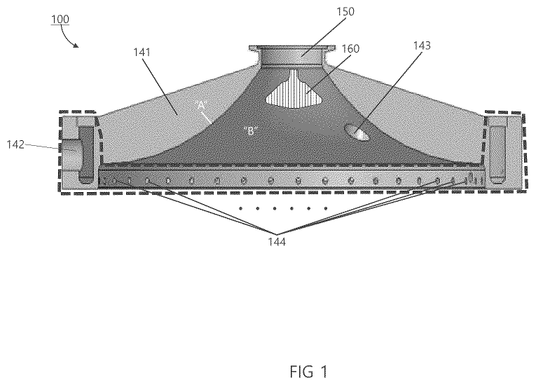

FIG. 1 illustrates an exemplary chamber structure according to one aspect of the present disclosure.

A reactor lid 100 according to the present disclosure comprises a top portion 141, a sidewall portion 142, a gas inlet 150, and a baffle 160.

The top portion 141 may be shaped as a truncated circular cone and a lower surface “A” of the top portion 141 may have a downward convex shape. The sidewall portion 142 may encircle the downside of the top portion 141.

The gas inlet 150 is connected to the truncated area of the top portion 140 for inserting generated plasma and processing gas into a wafer processing space “B” defined by the top portion 140 and the sidewall portion 142 to process wafers.

A remote plasma unit (not illustrated) may be placed above the gas inlet 150 so that the plasma generated in the remote plasma unit may be inserted into the wafer processing space “B” by the gas inlet 150. Also, gas insertion point(s) (not illustrated) may be located at the gas inlet 150 and processing gas from an outside gas source (not illustrated) may be inserted into the wafer processing space “B” via gas insertion point(s) through pipes (not illustrated).

The wafer processing space “B” may hold the generated plasma and/or the processing gas for enough time to process a wafer placed on a wafer support (disposed below the reactor lid 100 of FIG. 1)

The top portion 141 (more specifically, the top portion 141's lower surface “A”) and the sidewall portion 142, along with the wafer support, may define the wafer processing space “B,” in which a film may be deposited on the wafer.

A viewport 143 may or may not be placed on the top portion 141 for inspecting the process status.

The sidewall portion 142 may surround or encircle the downside of the top portion 141. The sidewall portion 142 may also comprise a plurality of holes 144 at the base of it as shown in FIG. 1. These holes are used for exhausting the processing gas after it is used for processing the wafers in the wafer processing space “B”.

A residence time of the processing gas on the wafer in the wafer processing space “B” may be important for wafer uniformity, and the processing gas may need to be pumped out when one stage of processing may be over. For this purpose, the distance between neighboring holes and/or the diameter of each hole may vary.

For example, the distance between neighboring holes may get shorter (i.e., more holes in the same length) as the holes may get nearer to a pumping port and/or the diameter of the holes may increase as the holes may get nearer to the pumping port.

The shortening of the distance and/or the increase in diameter, alone or combined, may affect an exit speed of the processing gas from the wafer processing space “B” to the pumping port, thus contributing to better wafer uniformity.

The baffle 160 may be placed at the mouth of the top portion 141 just below the gas inlet 150. The baffle 160 may disperse and divert the direction of a downpouring plasma and gas so that it would prevent plasma and gas from being excessively concentrated in the center area of the wafer placed in the wafer processing space “B”. The baffle 160 would be bell-shaped as shown in FIG. 1 for generating maximum plasma and gas vortex for dispersing it evenly on the surface of the wafer below.

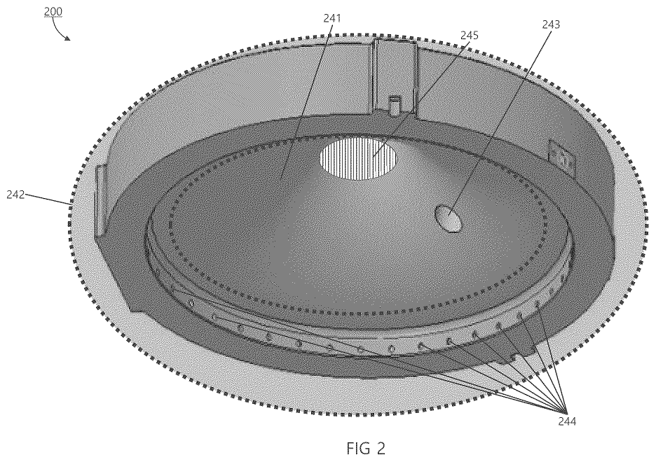

In FIG. 2, a reactor lid 200 viewed from its bottom is illustrated. A top portion 241 covers on top and a sidewall portion 242 encircles the downside of the top portion 241. Even though gas inlet may not be visible in this angle, a baffle 245 may be placed at the mouth of the gas inlet (not drawn). As specified above, a viewport 243 may or may not be placed on the top portion 241.

From this angle, a plurality of holes 244 in the side wall portion 242 are clearly depicted and visible. It may be noted that the distances of the neighboring holes may vary even though they may seem constant.

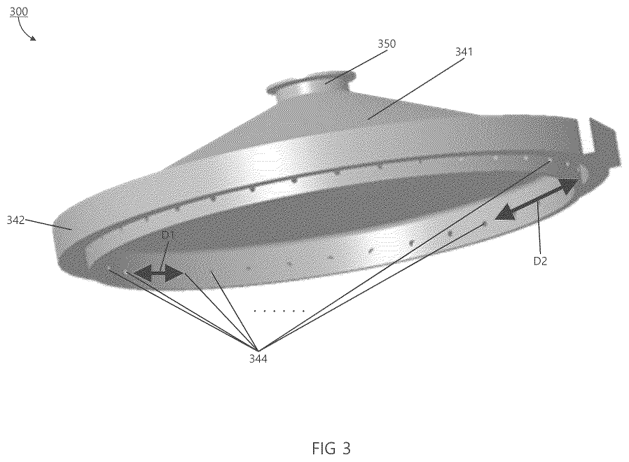

In FIG. 3, the distance difference among a plurality of holes 344 may be illustrated.

In a reactor lid 300, a top portion 341 may be encircled at the downside by a sidewall portion 342.

A gas inlet 350 may be placed at the top area of the top portion 341. The sidewall portion 342 may comprise a plurality of holes 344. As illustrated, the distance of any neighboring holes in the plurality of holes 344 in the sidewall portion 342 may vary. Distance ‘D1’ may be shorter than distance ‘D2’. The shorter the distance gets; the more holes exist in the same length. This distance difference may result from the position of a pumping port (not drawn). Though not shown, the diameter of the holes may also vary due to their relative position, i.e., its closeness to a pumping port (not drawn).

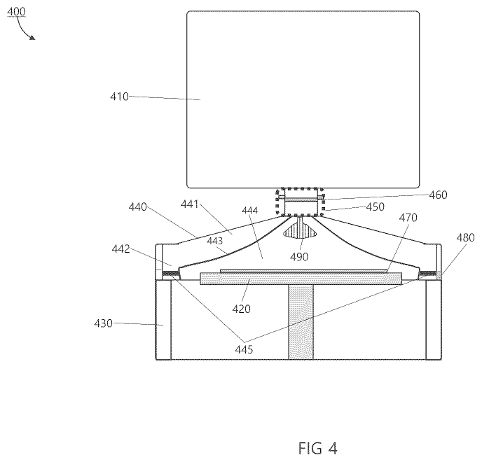

FIG. 4 illustrates the overall system diagram of a Plasma Enhanced Atomic Layer Deposition (PEALD) apparatus according to an embodiment of the present disclosure.

The PEALD apparatus may comprise a remote plasma unit 410, a gas inlet 450, an upper chamber 440, a lower chamber 430, a wafer support 420, and a pumping port 480.

A remote plasma unit 410 may generate plasma used for wafer processing. The generated plasma may be inserted into a reaction chamber 440 via a gas inlet 450.

A processing gas may be inserted into the reaction chamber 440 via the gas inlet 450. More specifically, the processing gas may be originated from an outer gas source (not illustrated) and may be transferred through pipes (not illustrated) from the outer gas source to the gas inlet 450 by the gas insertion point(s) 460. The gas insertion point(s) may be one or more holes in the gas inlet 450 which may be connected with the pipes from the outer gas source.

The plasma from the remote plasma unit 410 or the processing gas from an outer gas source would be poured down through the gas inlet 450.

The plasma and/or the processing gas via the gas inlet 450 may be used to process wafers in a space 444. This wafer processing space 444 would be defined by the upper chamber 440 and a wafer support 420. A wafer 470 may be placed on the wafer support 420 for processing.

The upper chamber 440 may comprise a top portion 441, a sidewall portion 442 and a baffle 490. The top portion 441 may have a truncated circular cone shape.

The gas inlet 450 may be disposed at the truncated area of the top portion 441 for the generated plasma and the processing gas to be inserted into a wafer processing space 444.

The top portion 441's downside surface 443 may be shaped downward convex. Experiments show that that smaller wafer processing space becomes, the higher the reaction efficiency gets. Therefore, the top portion 441's downside surface 443 may get more convex shape to make the wafer processing space 444 smaller.

The sidewall portion 442 may encircle or surround the downside of the top portion 441. As shown in FIGS. 1-3, the sidewall portion 442 may comprise a plurality of holes 445 around the bottom side of the sidewall portion for exhausting processing gas after processing the wafers.

For exhausting a processing gas after processing a wafer, a pumping port 480 may be disposed.

As stated above, the distance between the neighboring holes may get shorter as the holes may be located nearer to the pumping port 480. Also, it would also be noted that the diameter of the holes would get larger as the holes may be disposed nearer the pumping port 480.

This distance difference and/or diameter change, alone or combined together, may change the processing gas's residence time over the wafer so that the wafer uniformity would be improved.

The lower chamber 430 may be air-tight to maintain a vacuum state and may surround the wafer support 420.

A baffle 490 may be disposed at the mouth of the top portion 441 just below the gas inlet 450. The baffle 490 may prevent the plasma and the processing gas flowing downward from being concentrated at the center of the wafer 470.

The speed of the plasma and processing gas may create a vortex and turbulence to disperse the plasma and processing across the wafer 470 when hitting the baffle 490. This vortex and turbulence would improve the wafer uniformity.

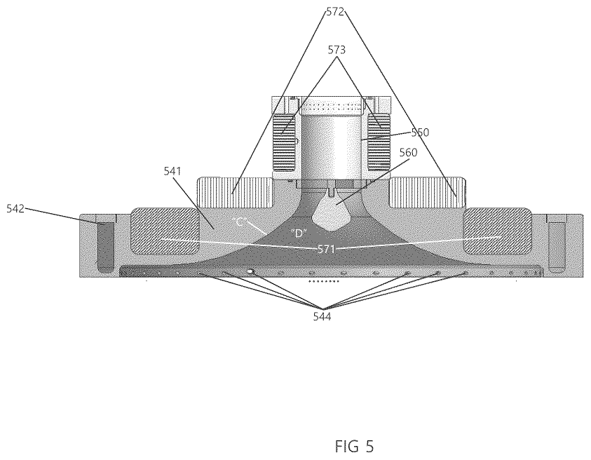

FIG. 5 illustrates another embodiment of a reactor lid according to the present disclosure.

The main differences of FIG. 5 against FIG. 4 may be that there may be more than 1 (one) heater on a top portion 541 and a gas inlet 550.

For better reaction efficiency, the downside of the top portion “C” would be more convex shaped downwardly to make a wafer processing space “D” smaller. A heater 571 may be disposed outside of the top portion 541 and another heater 572 may also be disposed on the top portion 541.

And a third heater 573 may be disposed around the gas inlet 550. And all the heaters 571, 572, 573 may be disposed to improve reaction efficiency.

The above-described arrangements of apparatus are merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. A reactor lid in an atomic layer deposition apparatus with a remote plasma unit to process wafers, the reactor lid comprising:
a gas inlet configured to flow a generated plasma and a processing gas into a wafer processing space;
a top portion disposed below the gas inlet and having a truncated circular cone shape, the top portion defining the wafer processing space for flowing the generated plasma and the processing gas;
a sidewall portion disposed below the top portion; and
a baffle placed at a mouth of the top portion below the gas inlet and configured to disperse the generated plasma and the processing gas throughout a surface of the wafer evenly by preventing the generated plasma and the processing gas from concentrating in the center of the wafer,
wherein the wafer processing space is also defined by the sidewall portion.

2. The reactor lid according to claim 1, wherein:
the sidewall portion further comprising a plurality of holes around the bottom side of the sidewall portion.

3. The reactor lid according to claim 1, wherein:
the top portion further configured to have a downward convex shape.

4. The reactor lid according to claim 2, wherein:
the distance between neighboring two holes varies.

5. The reactor lid according to claim 2, wherein:
the diameter of the holes in the plurality of holes varies.

6. A Plasma Enhanced Atomic Layer Deposition (PEALD) apparatus for processing wafers, the apparatus comprising:
a wafer support provided with a heater for supporting and heating a wafer;
a remote plasma unit configured to generate plasma;
a lower chamber configured to surround the wafer support;
an upper chamber disposed above the lower chamber and configured to define a wafer processing space for processing wafers; and
a gas inlet disposed to connect the remote plasma unit and the upper chamber, and the gas inlet being configured to flow the generated plasma from the remote plasma unit and a processing gas into the wafer processing space, wherein
the upper chamber further comprises:
a top portion disposed below the gas inlet and having a truncated circular cone shape, the top portion being configured to flow the generated plasma and the processing gas into the wafer processing space;
a sidewall portion disposed below the top portion; and
a baffle placed at the mouth of the top portion below the gas inlet and configured to disperse the generated plasma and the processing gas throughout a surface of the wafer evenly spread the generated plasma and the processing gas across a surface of the wafer, wherein
the wafer processing space being disposed below the top portion and surrounded by the sidewall portion and the wafer support.

7. The PEALD apparatus according to claim 6, wherein
the sidewall portion further comprising a plurality of holes around the bottom side of the sidewall portion.

8. The PEALD apparatus according to claim 6, wherein
the top portion further configured to have a downward convex shape.

9. The PEALD apparatus according to claim 7, further comprising:
a pumping port configured to exhaust the processing gas after processing wafers.

10. The PEALD apparatus according to claim 9, wherein
the distance between two neighboring holes of the plurality of holes would get shorter as the holes are located nearer to the pumping port.

11. The PEALD apparatus according to claim 9, wherein
the diameter of the holes of the plurality of holes would get larger as the holes are located nearer to the pumping port.

12. A reactor lid in an atomic layer deposition apparatus with a remote plasma unit to process wafers, the reactor lid comprising:
a gas inlet configured to flow a generated plasma gas and a processing gas into a wafer processing space;
a top portion disposed below the gas inlet and having a truncated circular cone shape, the top portion being configured to flow the generated plasma and dispersing a processing gas into a space below the top portion for processing the wafers;
a sidewall portion disposed below the top portion;
a baffle placed at the mouth of the top portion below the gas inlet and configured to prevent the generated plasma and the processing gas from concentrating in the center of the wafer; and
more than one heater disposed on the surface of the top portion and/or around the gas inlet.

13. The reactor lid according to claim 12, wherein:
the sidewall portion further comprising a plurality of holes around the bottom side of the sidewall portion.

14. The reactor lid according to claim 12, wherein:
the top portion has a downward convex shape on a side facing the wafer processing space.

15. The reactor lid according to claim 13, wherein:
the distance between neighboring two holes and/or the diameter of the holes in the plurality of holes varies.
